(19) United States
(12) Patent Application Publication
(10) Pub. No.: US 2026/0059991 A1
(43) Pub. Date: Feb. 26, 2026

(54) PIXEL ARRANGEMENT, DISPLAY SUBSTRATE, AND DISPLAY DEVICE

(71) Applicant: BOE TECHNOLOGY GROUP CO., LTD., Beijing (CN)

(72) Inventor: Wenxiu ZHU, Beijing (CN)

(73) Assignee: BOE TECHNOLOGY GROUP CO., LTD., Beijing (CN)

(21) Appl. No.: 18/996,229

(22) PCT Filed: Mar. 29, 2024
(86) PCT No.: PCT/CN2024/084770

§ 371 Date: Jan. 17, 2025

(30) Foreign Application Priority Data
Apr. 23, 2023 (CN) 202310442635.6

(51) Int. Cl. H10K 59/80; H10K 59/122; H10K 59/131

(52) U.S. Cl. CPC H10K 59/8792; H10K 59/122; H10K 59/131

(57) ABSTRACT

A pixel arrangement, a display substrate, and a display device are provided. The pixel arrangement includes a plurality of pixel groups, each of the plurality of pixel groups includes: a first pixel unit and a second pixel unit; the first pixel unit includes a plurality of display sub-pixels, the second pixel unit includes a plurality of anti-peeping sub-pixels, the first pixel unit is configured to display in a first state, and the second pixel unit is configured to display in a second state; and in the same pixel group, a first region defined by center connecting lines of the plurality of display sub-pixels is overlapped with a second region defined by center connecting lines of the plurality of anti-peeping sub-pixels.

### CROSS-REFERENCE TO RELATED APPLICATION

The patent application claims the priority of the Chinese patent application No. 202310442635.6 filed on Apr. 23, 2023, the entire disclosure of which is incorporated herein by reference as part of the present application.

### TECHNICAL FIELD

At least one embodiment of the present disclosure relates to a pixel arrangement, a display substrate and a display device.

### BACKGROUND

Display screens need to have an anti-peeping function (anti-peeping state) in some privacy scenarios, but if it is needed to share screen information (sharing state) in some public scenarios, the display screens must have a function of switching between the anti-peeping state and the sharing state at any time. For example, the display screen includes an Active-matrix organic light emitting diode (AMOLED) display screen.

### SUMMARY

At least one embodiment of the present disclosure relates to a pixel arrangement, a display substrate and a display device, aiming to better realize anti-peeping display.

Embodiments of the present disclosure provide a pixel arrangement, including a plurality of pixel groups, each of the plurality of pixel groups includes: a first pixel unit and a second pixel unit; the first pixel unit includes a plurality of display sub-pixels, the second pixel unit includes a plurality of anti-peeping sub-pixels, the first pixel unit is configured to display in a first state, and the second pixel unit is configured to display in a second state; and in the same pixel group, a first region defined by center connecting lines of the plurality of display sub-pixels is overlapped with a second region defined by center connecting lines of the plurality of anti-peeping sub-pixels.

In the pixel arrangement provided by an embodiment of the present disclosure, the second pixel unit is also configured to display in the first state.

In the pixel arrangement provided by an embodiment of the present disclosure, each of the plurality of display sub-pixels is annular and is provided with an opening, and one of the plurality of anti-peeping sub-pixels is arranged in the opening.

In the pixel arrangement provided by an embodiment of the present disclosure, an area of the first region is equal to that of the second region.

In the pixel arrangement provided by an embodiment of the present disclosure, the plurality of display sub-pixels include a first display sub-pixel, a second display sub-pixel, and a third display sub-pixel; the plurality of anti-peeping sub-pixels include a first anti-peeping sub-pixel, a second anti-peeping sub-pixel, and a third anti-peeping sub-pixel; the first display sub-pixel and the first anti-peeping sub-pixel are configured to emit light of a first color; the second display sub-pixel and the second anti-peeping sub-pixel are configured to emit light of a second color; and the third display sub-pixel and the third anti-peeping sub-pixel are configured to emit light of a third color.

In the pixel arrangement provided by an embodiment of the present disclosure, the first display sub-pixel is annular and is provided with a first opening, and the first anti-peeping sub-pixel is arranged in the first opening; the second display sub-pixel is annular and is provided with a second opening, and the second anti-peeping sub-pixel is arranged in the second opening; and the third display sub-pixel is annular and is provided with a third opening, and the third anti-peeping sub-pixel is arranged in the third opening.

In the pixel arrangement provided by an embodiment of the present disclosure, the center connecting line of the first display sub-pixel and the second display sub-pixel coincides with the center connecting line of the first anti-peeping sub-pixel and the second anti-peeping sub-pixel.

In the pixel arrangement provided by an embodiment of the present disclosure, the first display sub-pixel and the first anti-peeping sub-pixel are adjacent to each other, the second display sub-pixel and the second anti-peeping sub-pixel are adjacent to each other, and the third display sub-pixel and the third anti-peeping sub-pixel are adjacent to each other.

In the pixel arrangement provided by an embodiment of the present disclosure, in the same pixel group, the center connecting line of the first display sub-pixel and the second display sub-pixel is not overlapped or is partially overlapped with the center connecting line of the first anti-peeping sub-pixel and the second anti-peeping sub-pixel.

In the pixel arrangement provided by an embodiment of the present disclosure, an extension direction of the first display sub-pixel is the same as that of the first anti-peeping sub-pixel, an extension direction of the second display sub-pixel is the same as that of the second anti-peeping sub-pixel, and an extension direction of the third display sub-pixel is the same as that of the third anti-peeping sub-pixel.

In the pixel arrangement provided by an embodiment of the present disclosure, the extension direction of the first display sub-pixel, the extension direction of the first anti-peeping sub-pixel, the extension direction of the second display sub-pixel, the extension direction of the second anti-peeping sub-pixel, the extension direction of the third display sub-pixel, and the extension direction of the third anti-peeping sub-pixel are all the same.

In the pixel arrangement provided by an embodiment of the present disclosure, each of the plurality of display sub-pixels is obliquely arranged, each of the plurality of anti-peeping sub-pixels is obliquely arranged, and the display sub-pixel and the anti-peeping sub-pixel have the same oblique angle.

In the pixel arrangement provided by an embodiment of the present disclosure, an area of the first anti-peeping sub-pixel is smaller than or equal to an area of the first display sub-pixel, an area of the second anti-peeping sub-pixel is smaller than or equal to an area of the second display sub-pixel, and an area of the third anti-peeping sub-pixel is smaller than or equal to an area of the third display sub-pixel.

In the pixel arrangement provided by an embodiment of the present disclosure, a center distance of the first display sub-pixel and the second display sub-pixel is the same as a center distance of the first anti-peeping sub-pixel and the second anti-peeping sub-pixel.

Embodiments of the present disclosure further provide a display substrate, including: a base substrate; and a plurality of pixels arranged on the base substrate; and the plurality of pixels adopt any one of the pixel arrangements as described above.

In the display substrate provided by an embodiment of the present disclosure, at least one of the plurality of display sub-pixels in the first pixel unit and at least one of the plurality of anti-peeping sub-pixels in the second pixel unit share one same pixel circuit.

In the display substrate provided by an embodiment of the present disclosure, the pixel circuit includes a switching transistor; and the pixel circuit is connected to a first electrode of one of the plurality of anti-peeping sub-pixels, and the pixel circuit is connected to a first electrode of one of the plurality of display sub-pixels through the switching transistor.

In the display substrate provided by an embodiment of the present disclosure, the display substrate further includes a pixel defining layer, the pixel defining layer is provided with a main body part and a pixel opening, and one of the plurality of display sub-pixels and one of the plurality of anti-peeping sub-pixels are separated by a part of the main body part.

In the display substrate provided by an embodiment of the present disclosure, the display substrate further includes a first black matrix and a second black matrix, the first black matrix is located on a side of the plurality of pixels facing away from the base substrate, and the second black matrix is located on a side of the first black matrix facing away from the base substrate; the first black matrix is provided with a first hollowed-out region and a second hollowed-out region; and the second black matrix is provided with a third hollowed-out region and a fourth hollowed-out region; an orthographic projection of the first hollowed-out region on the base substrate is overlapped with an orthographic projection of one of the plurality of display sub-pixels on the base substrate; an orthographic projection of the third hollowed-out region on the base substrate is overlapped with the orthographic projection of the display sub-pixel on the base substrate; an orthographic projection of the second hollowed-out region on the base substrate is overlapped with an orthographic projection of one of the plurality of anti-peeping sub-pixels on the base substrate; an orthographic projection of the fourth hollowed-out region on the base substrate is overlapped with the orthographic projection of the anti-peeping sub-pixel on the base substrate; an area of the third hollowed-out region is larger than that of the first hollowed-out region; and an area of the fourth hollowed-out region is equal to that of the second hollowed-out region.

In the display substrate provided by an embodiment of the present disclosure, each of the plurality of display sub-pixels includes a first light emitting element; each of the plurality of anti-peeping sub-pixels includes a second light emitting element; each of the first light emitting element and the second light emitting element includes a first electrode, a second electrode, and a light emitting functional layer located between the first electrode and the second electrode; the first electrode is closer to the base substrate than the second electrode; the first electrode of the first light emitting element and the first electrode of the second light emitting element are spaced apart from each other; and in the same pixel group, the anti-peeping sub-pixel and the display sub-pixel that are closest in distance have the same light emitting color.

Embodiments of the present disclosure further provide a display device, including any one of the display substrates as described above.

### BRIEF DESCRIPTION OF DRAWINGS

In order to more clearly illustrate the technical solution of the embodiments of the present disclosure, the drawings of the embodiments will be briefly described in the following. Apparently, the described drawings in the following are only related to some embodiments of the present disclosure without any limitation to the present disclosure.

FIG. 1 shows an S-stripe original pixel arrangement.

FIG. 2 is a schematic diagram of a pixel arrangement provided by an embodiment of the present disclosure.

FIG. 3 is a schematic diagram of another pixel arrangement provided by an embodiment of the present disclosure.

FIG. 4 is a schematic diagram of another pixel arrangement provided by an embodiment of the present disclosure.

FIG. 5 is a schematic diagram of another pixel arrangement provided by an embodiment of the present disclosure.

FIG. 6 shows a blue diamond original pixel arrangement.

FIG. 7A is a schematic diagram of a pixel arrangement provided by an embodiment of the present disclosure.

FIG. 7B is a schematic diagram of a pixel arrangement provided by an embodiment of the present disclosure.

FIG. 8 is a schematic diagram of another pixel arrangement provided by an embodiment of the present disclosure.

FIG. 9 shows a GGRB original pixel arrangement.

FIG. 10 is a schematic diagram of a pixel arrangement provided by an embodiment of the present disclosure.

FIG. 11 is a schematic diagram of another pixel arrangement provided by an embodiment of the present disclosure.

FIG. 12 is a schematic diagram of another pixel arrangement provided by an embodiment of the present disclosure.

FIG. 13 is a schematic diagram of a pixel arrangement provided by an embodiment of the present disclosure.

FIG. 14A is a schematic diagram of a display substrate provided by an embodiment of the present disclosure.

FIG. 14B is a schematic diagram of a display substrate provided by an embodiment of the present disclosure.

FIG. 15 is a sectional view of a display substrate provided by an embodiment of the present disclosure.

FIG. 16 is a plan view of a black matrix BM1 in a display substrate provided by an embodiment of the present disclosure.

FIG. 17 is a plan view of a black matrix BM1 and a local light emitting layer EMF in a display substrate provided by an embodiment of the present disclosure.

FIG. 18 is a plan view of a black matrix BM2 in a display substrate provided by an embodiment of the present disclosure.

FIG. 19 is a plan view of a black matrix BM2 and a local light emitting layer EMF in a display substrate provided by an embodiment of the present disclosure.

FIG. 20 is a schematic diagram of connection between a pixel circuit and a light emitting element in a display substrate provided by an embodiment of the present disclosure.

FIG. 21 is a schematic diagram of a display substrate provided by an embodiment of the present disclosure.

FIG. 22 is a schematic diagram of a display substrate provided by an embodiment of the present disclosure.

FIG. 23 is a schematic diagram of connection between a pixel circuit and a light emitting element in a display substrate provided by another embodiment of the present disclosure.

### DETAILED DESCRIPTION

In order to make objectives, technical details, and advantages of the embodiments of the present disclosure more clearly, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the present disclosure, are not intended to indicate any sequence, amount or importance, but distinguish various components. Also, the words such as “a”, “an” or “the” do not indicate a quantity limit, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the described object is changed, the relative position relationship may be changed accordingly.

In order to realize a switchable anti-peeping display function of a display screen, it is needed to design a current mainstream pixel arrangement mode to meet switchable anti-peeping display.

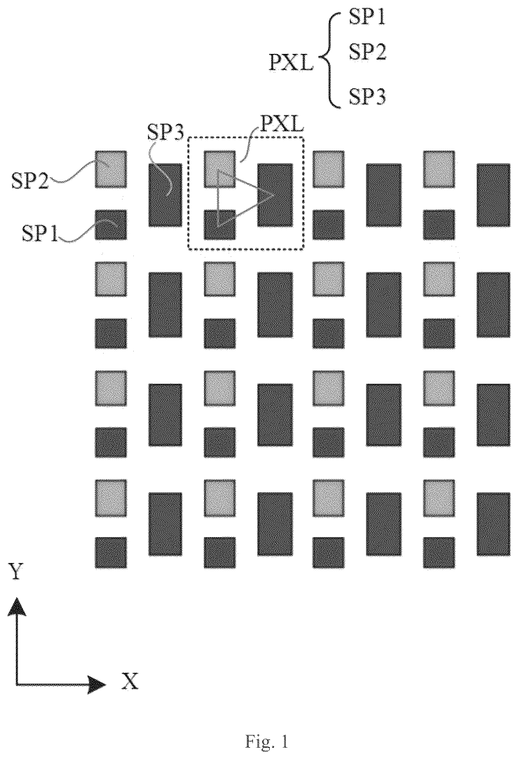

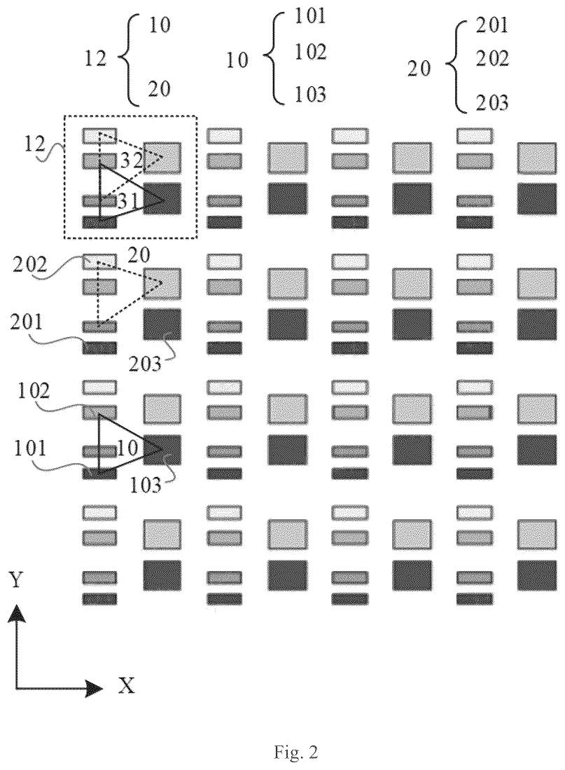

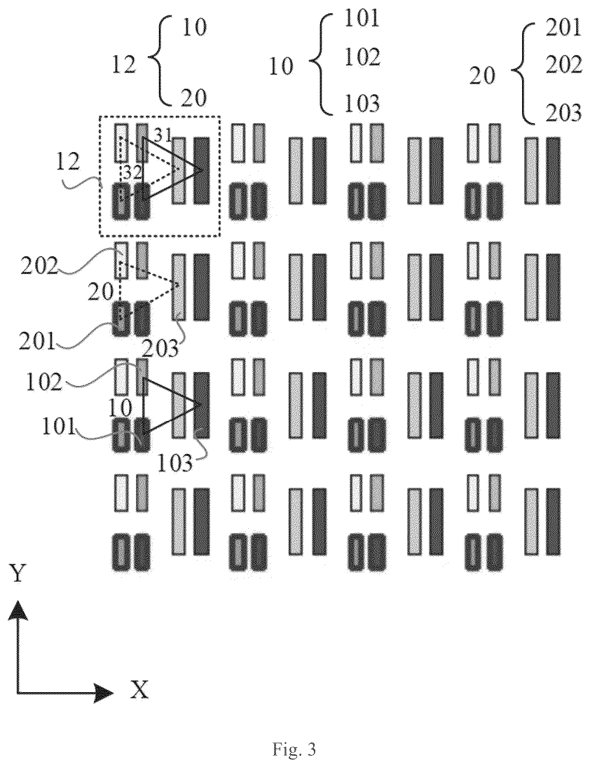

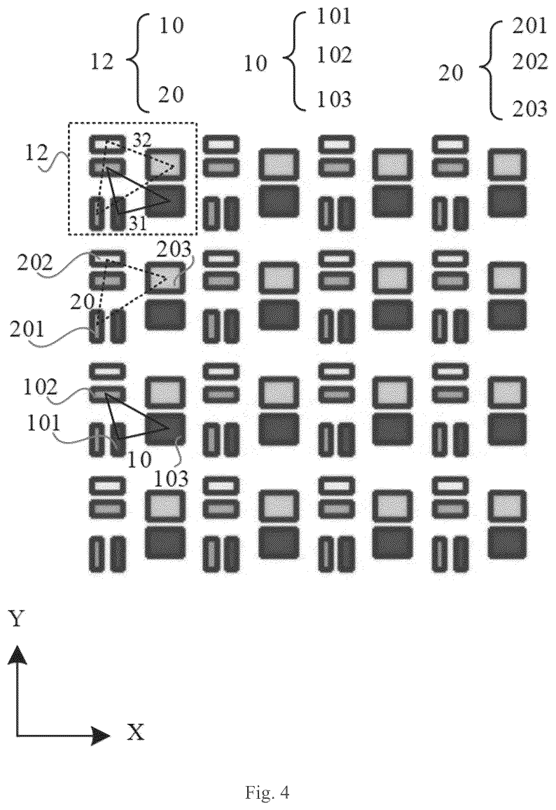

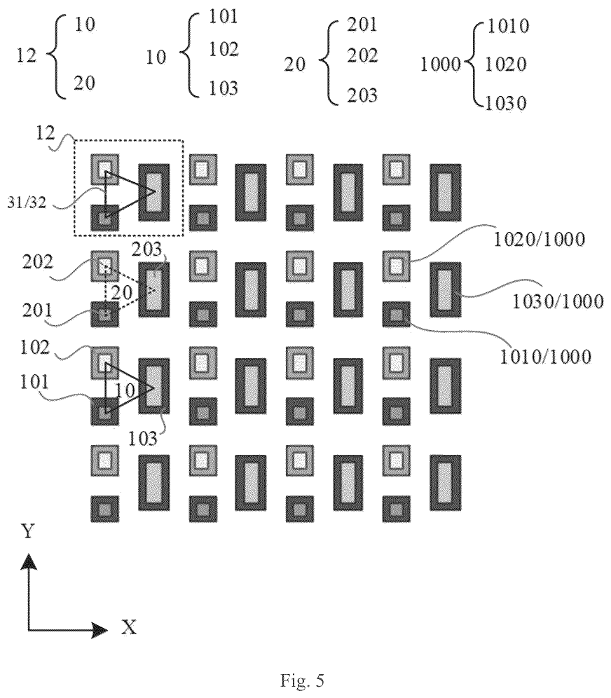

FIG. 1 shows an S-stripe original pixel arrangement. FIG. 2 is a schematic diagram of a pixel arrangement provided by an embodiment of the present disclosure. FIG. 3 is a schematic diagram of another pixel arrangement provided by an embodiment of the present disclosure. FIG. 4 is a schematic diagram of another pixel arrangement provided by an embodiment of the present disclosure. FIG. 5 is a schematic diagram of another pixel arrangement provided by an embodiment of the present disclosure. FIG. 2 to FIG. 5 are several schematic diagrams of the pixel arrangement formed by cutting based on the pixel arrangement shown in FIG. 1.

As shown in FIG. 1, a pixel unit PXL includes a sub-pixel SP1, a sub-pixel SP2, and a sub-pixel SP3. The sub-pixel SP1 and the sub-pixel SP2 are arranged in a direction Y, and are located on one side of the sub-pixel SP3.

The pixel arrangement shown in FIG. 2 can be regarded as that each sub-pixel in the pixel arrangement shown in FIG. 1 is transversely cut, namely, the sub-pixel shown in FIG. 1 is cut into two sub-pixels in a direction X, one of the two sub-pixels is used as a display sub-pixel, and the other one of the two sub-pixels is used as an anti-peeping sub-pixel.

The pixel arrangement shown in FIG. 3 can be regarded as that each sub-pixel in the pixel arrangement shown in FIG. 1 is vertically cut, namely, the sub-pixel shown in FIG. 1 is cut into two sub-pixels in the direction Y, one of the two sub-pixels is used as the display sub-pixel, and the other one of the two sub-pixels is used as the anti-peeping sub-pixel.

The pixel arrangement shown in FIG. 4 can be regarded as that part of sub-pixels in the pixel arrangement shown in FIG. 1 are vertically cut, and the other part of the sub-pixels are transversely cut, namely, the sub-pixel shown in FIG. 1 is cut into two sub-pixels in the direction X or the direction Y, one of the two sub-pixels is used as the display sub-pixel, and the other one of the two sub-pixels is used as the anti-peeping sub-pixel. The pixel arrangement shown in FIG. 4 can be regarded as that the sub-pixel SP1 in the pixel arrangement shown in FIG. 1 is vertically cut, and the sub-pixel SP2 and the sub-pixel SP3 are transversely cut.

The pixel arrangement shown in FIG. 5 can be regarded as that each sub-pixel in the pixel arrangement shown in FIG. 1 is annularly cut, namely, the sub-pixel shown in FIG. 1 is annularly cut into two sub-pixels, one of the two sub-pixels is annular and is located outside the other sub-pixel, one of the two sub-pixels is used as the display sub-pixel, and the other one of the two sub-pixels is used as the anti-peeping sub-pixel.

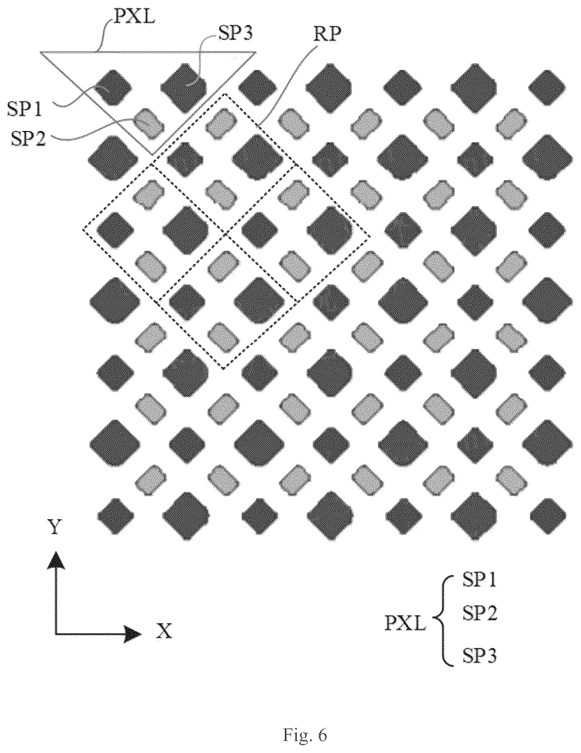

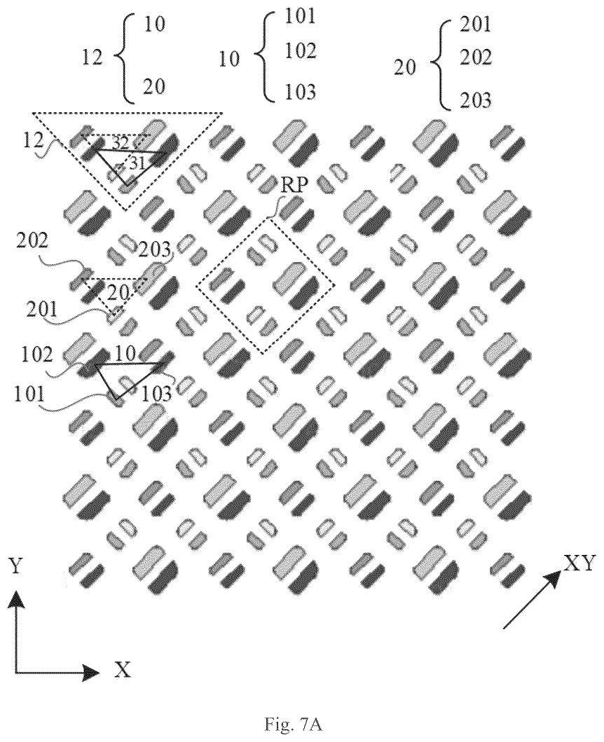

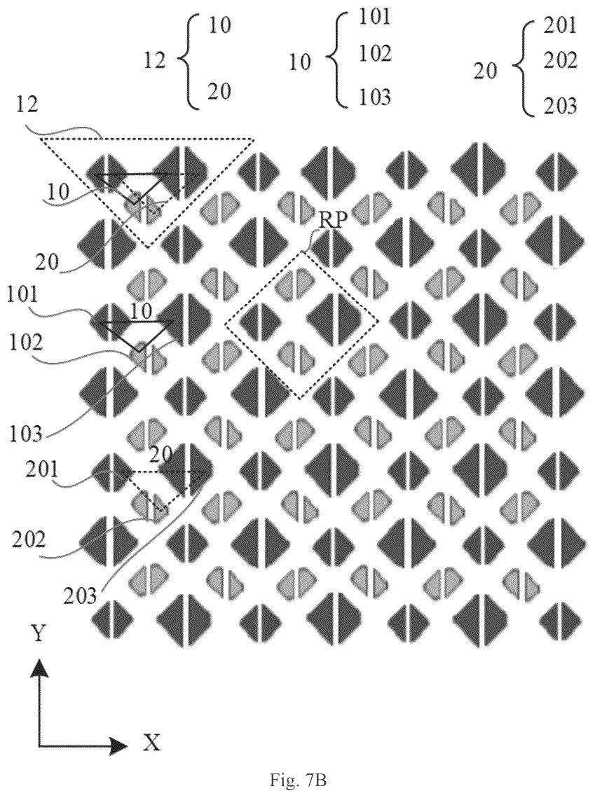

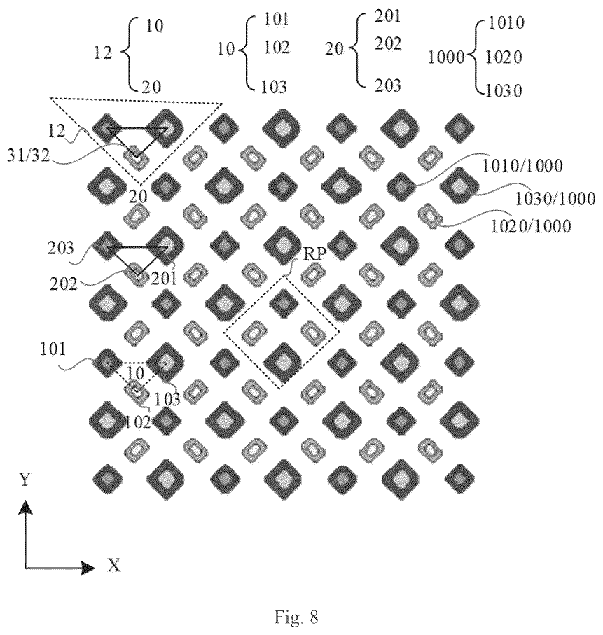

FIG. 6 shows a blue diamond original pixel arrangement. FIG. 7A is a schematic diagram of a pixel arrangement provided by an embodiment of the present disclosure. FIG. 7B is a schematic diagram of a pixel arrangement provided by an embodiment of the present disclosure. FIG. 8 is a schematic diagram of another pixel arrangement provided by an embodiment of the present disclosure. FIG. 7A to FIG. 8 are several schematic diagrams of the pixel arrangement formed by cutting based on the pixel arrangement shown in FIG. 6.

As shown in FIG. 6, the pixel unit PXL includes the sub-pixel SP1, the sub-pixel SP2 and the sub-pixel SP3. The sub-pixel SP1 and the sub-pixel SP3 are arranged in the direction X, and are located on one side of the sub-pixel SP2 in the direction Y.

As shown in FIG. 6, one sub-pixel SP1, two sub-pixels SP2 and one sub-pixel SP3 form a repeat unit RP. A plurality of repeat units RP are arranged in an array.

As shown in FIG. 6, the sub-pixel SP1 and the sub-pixel SP3 are shared sub-pixels.

The pixel arrangement shown in the FIG. 7A can be regarded as that each sub-pixel in the pixel arrangement shown in FIG. 6 is obliquely cut, namely, the sub-pixel shown in the FIG. 6 is cut into two sub-pixels in a direction XY, one of the two sub-pixels is used as the display sub-pixel, and the other one of the two sub-pixels is used as the anti-peeping sub-pixel. The direction XY is a direction different from the direction X and different from the direction Y in the plane where the direction X and the direction Y are located. An included angle is formed between the direction XY and the direction X, and an included angle is formed between the direction XY and the direction Y. The included angle between the direction XY and the direction X and the included angle between the direction XY and the direction Y can be determined according to needs.

The pixel arrangement shown in the FIG. 7B can be regarded as that each sub-pixel in the pixel arrangement shown in the FIG. 6 is vertically cut, namely, the sub-pixel shown in the FIG. 6 is cut into two sub-pixels in the direction Y, one of the two sub-pixels is used as the display sub-pixel, and the other one of the two sub-pixels is used as the anti-peeping sub-pixel. In FIG. 7B, that the two sub-pixels obtained by vertically cutting (uniform cutting) one sub-pixel have the same area is taken as an example for illustrating, but it is not limited to this. An area relationship between the display sub-pixel and the anti-peeping sub-pixel can be determined according to needs. Definitely, the sub-pixels emitting light of different colors may be different in area.

The pixel arrangement shown in FIG. 8 can be regarded as that each sub-pixel in the pixel arrangement shown in the FIG. 6 is annularly cut, namely, the sub-pixel shown in the FIG. 6 is annularly cut into two sub-pixels, one of the two sub-pixels is annular and is located outside the other sub-pixel, one of the two sub-pixels is used as the display sub-pixel, and the other one of the two sub-pixels is used as the anti-peeping sub-pixel.

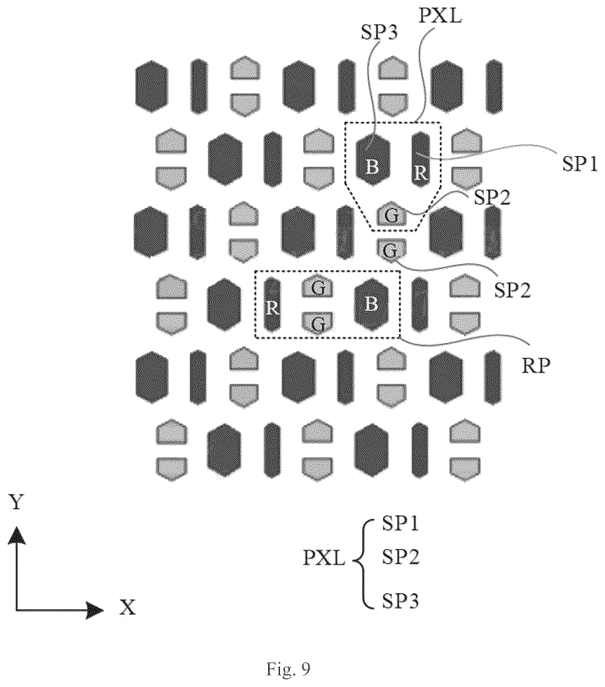

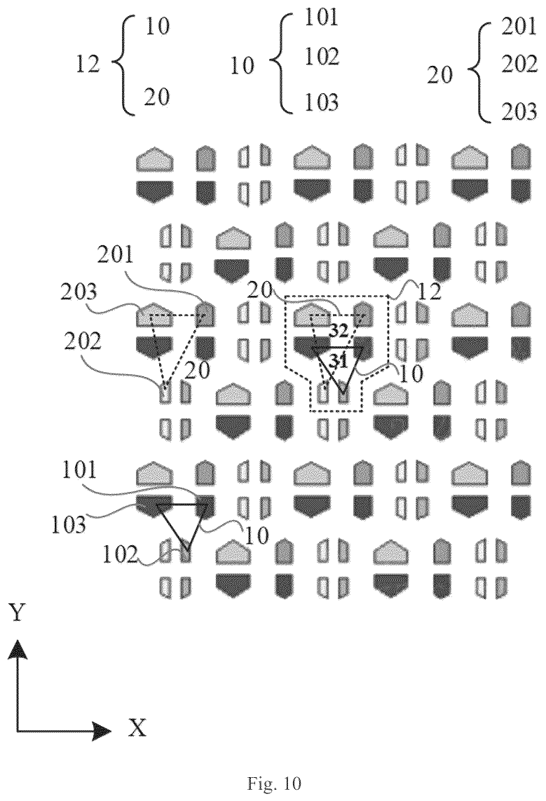

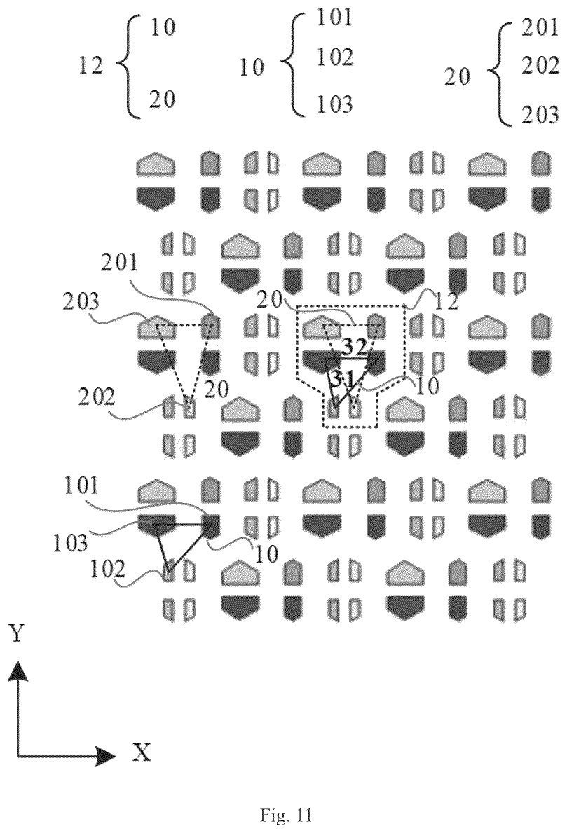

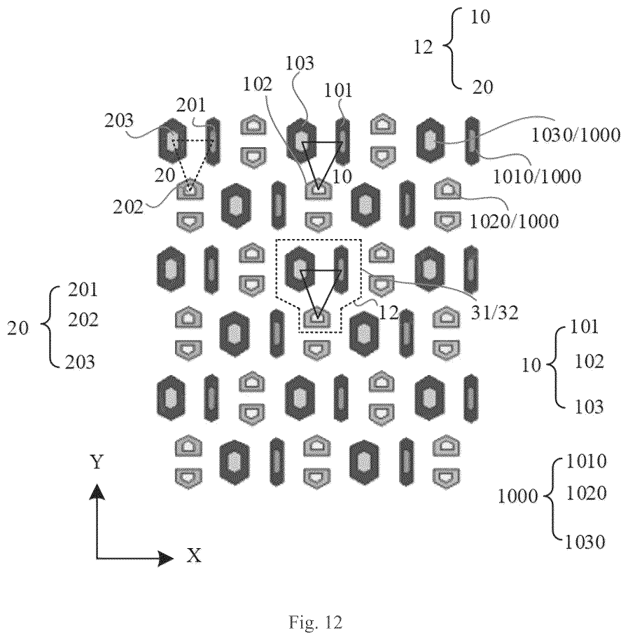

FIG. 9 shows a GGRB original pixel arrangement. FIG. 10 is a schematic diagram of a pixel arrangement provided by an embodiment of the present disclosure. FIG. 11 is a schematic diagram of another pixel arrangement provided by an embodiment of the present disclosure. FIG. 12 is a schematic diagram of another pixel arrangement provided by an embodiment of the present disclosure. FIG. 10 to FIG. 12 are several schematic diagrams of the pixel arrangement formed by cutting based on the pixel arrangement shown in FIG. 9.

As shown in FIG. 9, the pixel unit PXL includes the sub-pixel SP1, the sub-pixel SP2, and the sub-pixel SP3. The sub-pixel SP1 and the sub-pixel SP3 are arranged in the direction X, and are located on one side of the sub-pixel SP2 in the direction Y. As shown in FIG. 9, one sub-pixel SP1, two sub-pixels SP2 and one sub-pixel SP3 form the repeat unit RP. The repeat units RP of every two adjacent rows of sub-pixels are arranged in a staggered manner. As shown in FIG. 9, the two sub-pixels SP2 are arranged in the direction Y, and one sub-pixel SP1 and one sub-pixel SP3 are respectively arranged on two sides of the two sub-pixels SP2 in the direction X. The two sub-pixels SP2 are located between one sub-pixel SP1 and one sub-pixel SP3.

As shown in FIG. 9, the sub-pixel SP1 and the sub-pixel SP3 are shared sub-pixels.

The pixel arrangement shown in FIG. 10 and FIG. 11 can be regarded as that part of sub-pixels in the pixel arrangement shown in FIG. 9 are vertically cut, and the other part of sub-pixels are transversely cut, namely, the sub-pixel shown in FIG. 9 is cut into two sub-pixels in the direction X or the direction Y, one of the two sub-pixels is used as the display sub-pixel, and the other one of the two sub-pixels is used as the anti-peeping sub-pixel. The pixel arrangement shown in FIG. 10 and FIG. 11 can be regarded as that the sub-pixels SP2 in the pixel arrangement shown in FIG. 1 are vertically cut, and the sub-pixel SP1 and the sub-pixel SP3 are transversely cut.

The pixel arrangement shown in FIG. 12 can be regarded as that each sub-pixel in the pixel arrangement shown in FIG. 9 is annularly cut, namely, the sub-pixel shown in FIG. 9 is annularly cut into two sub-pixels, one of the two sub-pixels is annular and is located outside the other sub-pixel, one of the two sub-pixels is used as the display sub-pixel, and the other one of the two sub-pixels is used as the anti-peeping sub-pixel.

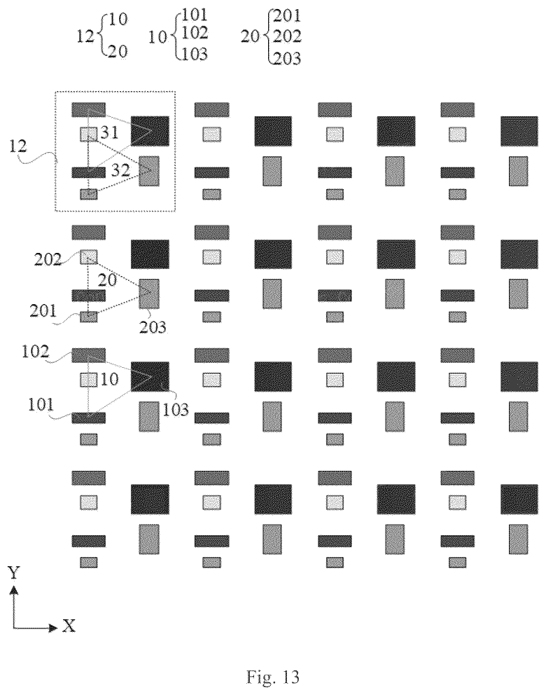

FIG. 13 is a schematic diagram of a pixel arrangement provided by an embodiment of the present disclosure. By taking the original pixel arrangement in an S-stripe form as an example, in order to further reduce large-view-angle brightness in the anti-peeping state, the size of the anti-peeping sub-pixel can be reduced, and the size of the display sub-pixel can be increased.

As shown in FIG. 2 to FIG. 5, FIG. 7A to FIG. 8, and FIG. 10 to FIG. 13, the embodiment of the present disclosure provides the pixel arrangement, and the pixel arrangement includes: a plurality of pixel groups 12; each pixel group 12 includes: a pixel unit 10 and a pixel unit 20; each pixel unit 10 includes a plurality of display sub-pixels 100, and each pixel unit 20 includes a plurality of anti-peeping sub-pixels 200; each pixel unit 10 is configured to display in a first state; and each pixel unit 20 is configured to display in a second state. For example, the first state is the sharing state, and the second state is the anti-peeping state.

According to the pixel arrangement provided by the embodiment of the present disclosure, one pixel group 12 is provided with the pixel unit 10 configured to display in the first state and the pixel unit 20 configured to display in the second state, so that display can be performed in different states. One pixel group 12 is provided with the pixel unit 10 and the pixel unit 20, which facilitates display in the first state of the pixel unit 10, and display in the second state of the pixel unit 20.

For example, in the pixel arrangement provided by the embodiment of the present disclosure, in order to improve the display quality of the first state (sharing state), the pixel units 20 are also configured to display in the first state.

In some embodiments, in the second state, only the pixel units 20 perform display; and in the first state, the pixel units 10 perform display, and the pixel units 20 may perform or may not perform display.

For example, as shown in FIG. 2 to FIG. 5, FIG. 7A to FIG. 8, and FIG. 10 to FIG. 13, in the pixel arrangement provided by the embodiment of the present disclosure, in the same pixel group 12, a first region 31 defined by center connecting lines of the plurality of display sub-pixels 100 is overlapped with a second region 32 defined by center connecting lines of the plurality of anti-peeping sub-pixels 200.

In some embodiments of the present disclosure, for the same pixel group 12, the display sub-pixels 100 and the anti-peeping sub-pixels 200 are arranged adjacently, so that the first region 31 defined by the center connecting lines of the plurality of display sub-pixels 100 is overlapped with the second region 32 defined by the center connecting lines of the plurality of anti-peeping sub-pixels 200. In the anti-peeping state and the sharing state, the difference of display images is small.

For example, in the embodiment of the present disclosure, the center of the sub-pixel may be the gravity center of the sub-pixel, but it is not limited to this. The center of the sub-pixel may be intersection point of symmetry axis of the sub-pixel parallel to the direction X and symmetry axis of the sub-pixel parallel to the direction Y, but it is not limited to this. The sub-pixel may be the display sub-pixel 100 and may also be the anti-peeping sub-pixel 200.

For example, as shown in FIG. 5, FIG. 8 and FIG. 12, in the pixel arrangement provided by the embodiment of the present disclosure, the display sub-pixels 100 are annular and are provided with openings 1000, and one of the plurality of anti-peeping sub-pixels 200 is arranged in the corresponding opening 1000.

In the case of annular cutting, the anti-peeping sub-pixel 200 is arranged in the annular display sub-pixel 100 located at the periphery, and therefore the center of the display sub-pixel 100 coincides with the center of the anti-peeping sub-pixel 200.

For example, in the pixel arrangement provided by the embodiment of the present disclosure, the area of the first region 31 is equal to that of the second region 32.

In the case of annular cutting, because the center of the display sub-pixel 100 can coincide with the center of the anti-peeping sub-pixels 200, the area of the first region 31 can be equal to that of the second region 32.

In the case of non-annular cutting, generally, the area of the first region 31 is not equal to that of the second region 32.

For example, as shown in FIG. 2 to FIG. 5, FIG. 7A to FIG. 8, and FIG. 10 to FIG. 13, in the pixel arrangement provided by the embodiment of the present disclosure, the plurality of display sub-pixel 100 include a first display sub-pixel 101, a second display sub-pixel 102 and a third display sub-pixel 103; the plurality of anti-peeping sub-pixel 200 include a first anti-peeping sub-pixel 201, a second anti-peeping sub-pixel 202 and a third anti-peeping sub-pixel 203; the first display sub-pixel 101 and the first anti-peeping sub-pixel 201 are configured to emit light of a first color; the second display sub-pixel 102 and the second anti-peeping sub-pixel 202 are configured to emit light of a second color; and the third display sub-pixel 103 and the third anti-peeping sub-pixel 203 are configured to emit light of a third color.

In the embodiment of the present disclosure, that the light of the first color is red light, the light of the second color is green light and the light of the third color is blue light is taken as an example for illustrating.

As shown in FIG. 2 to FIG. 5, FIG. 7A to FIG. 8, and FIG. 10 to FIG. 13, the first display sub-pixel 101 and the first anti-peeping sub-pixel 201 are close to each other, the second display sub-pixel 102 and the second anti-peeping sub-pixel 202 are close to each other, and the third display sub-pixel 103 and the third anti-peeping sub-pixel 203 are close to each other.

In some embodiments of the present disclosure, each sub-pixel in the original pixel arrangement is cut into two sub-pixels (the first display sub-pixel 101 and the anti-peeping sub-pixel 200), and the two sub-pixels are close to each other and emit light of the same color, which facilitates layout arrangement and process manufacturing.

For example, as shown in FIG. 5, FIG. 8, and FIG. 12, in the pixel arrangement provided by the embodiment of the present disclosure, the first display sub-pixel 101 is annular and is provided with first opening 1010, and the first anti-peeping sub-pixel 201 is arranged in the first opening 1010; the second display sub-pixel 102 is annular and is provided with second opening 1020, and the second anti-peeping sub-pixel 202 is arranged in the second opening 1020; the third display sub-pixel 103 is annular and is provided with third opening 1030, and the third anti-peeping sub-pixel 203 is arranged in the third opening 1030.

In some embodiments of the present disclosure, the display sub-pixel is annular and is arranged outside the anti-peeping sub-pixel, and the anti-peeping sub-pixel is arranged in the opening of the annular display sub-pixel.

For example, in the pixel arrangement provided by the embodiment of the present disclosure, the center connecting line of the first display sub-pixel 101 and the second display sub-pixel 102 coincides with the center connecting line of the first anti-peeping sub-pixel 201 and the second anti-peeping sub-pixel 202.

In some embodiments of the present disclosure, the distance from the first display sub-pixel 101 to the second display sub-pixel 102 is the same as the distance from the first anti-peeping sub-pixel 201 to the second anti-peeping sub-pixel 202.

For example, as shown in FIG. 5, FIG. 8 and FIG. 12, the center of the first display sub-pixel 101 coincides with the center of the first anti-peeping sub-pixel 201, the center of the second display sub-pixel 102 coincides with the center of the second anti-peeping sub-pixel 202, and the center of the third display sub-pixel 103 coincides with the center of the third anti-peeping sub-pixel 203.

According to the embodiment of the present disclosure, in the case of annular cutting, that the center of the display sub-pixel coincides with the center of the anti-peeping sub-pixel is taken as an example for illustrating, which facilitates the improvement of the display quality. However, in other embodiments, even in the case of annular cutting, the center of the display sub-pixel may not coincide with the center of the anti-peeping sub-pixel.

For example, as shown in FIG. 2 to FIG. 5, FIG. 7A to FIG. 8, and FIG. 10 to FIG. 13, in the pixel arrangement provided by the embodiment of the present disclosure, the first display sub-pixel 101 and the first anti-peeping sub-pixel 201 are adjacent to each other, the second display sub-pixel 102 and the second anti-peeping sub-pixel 202 are adjacent to each other, and the third display sub-pixel 103 and the third anti-peeping sub-pixel 203 are adjacent to each other.

In some embodiments of the present disclosure, the display sub-pixel and the anti-peeping sub-pixel are arranged adjacently, so that the display quality is improved, and the difference between an image in the anti-peeping state and an image in the sharing state is reduced.

For example, as shown in FIG. 2 to FIG. 5, FIG. 7A to FIG. 8, and FIG. 10 to FIG. 13, in the pixel arrangement provided by the embodiment of the present disclosure, in the same pixel group 12, the center connecting line of the first display sub-pixel 101 and the second display sub-pixel 102 is not overlapped or is partially overlapped with the center connecting line of the first anti-peeping sub-pixel 201 and the second anti-peeping sub-pixel 202.

For example, as shown in FIG. 3 to FIG. 4, FIG. 7A to FIG. 8, and FIG. 10, in the pixel arrangement provided by the embodiment of the present disclosure, in the same pixel group 12, the center connecting line of the first display sub-pixel 101 and the second display sub-pixel 102 is not overlapped with the center connecting line of the first anti-peeping sub-pixel 201 and the second anti-peeping sub-pixel 202.

For example, as shown in FIG. 2, FIG. 7A, FIG. 7B, FIG. 11, and FIG. 13, in the pixel arrangement provided by the embodiment of the present disclosure, in the same pixel group 12, the center connecting line of the first display sub-pixel 101 and the second display sub-pixel 102 is partially overlapped with the center connecting line of the first anti-peeping sub-pixel 201 and the second anti-peeping sub-pixel 202.

In some embodiments of the present disclosure, in the case of non-annular cutting, such as transverse cutting, vertical cutting or oblique cutting, the central connecting line of the first display sub-pixel 101 and the second display sub-pixel 102 are not overlapped or are partially overlapped with the central connecting line of the first anti-peeping sub-pixel 201 and the second anti-peeping sub-pixel 202.

For example, as shown in FIG. 2 to FIG. 4, FIG. 7A, FIG. 7B, and FIG. 10 to FIG. 11, in the pixel arrangement provided by the embodiments of the present disclosure, extension direction of the first display sub-pixel 101 is the same as that of the first anti-peeping sub-pixel 201, the extension direction of the second display sub-pixel 102 is the same as that of the second anti-peeping sub-pixel 202, and the extension direction of the third display sub-pixel 103 is the same as that of the third anti-peeping sub-pixel 203.

In some embodiments of the present disclosure, in the case of non-annular cutting, such as transverse cutting, vertical cutting or oblique cutting, the sub-pixels emitting light of the same color can be subjected to the same cutting mode.

For example, as shown in FIG. 2 to FIG. 4, FIG. 7A, FIG. 7B, and FIG. 10 to FIG. 11, in the pixel arrangement provided by the embodiments of the present disclosure, the extension direction of the first display sub-pixel 101, the extension direction of the first anti-peeping sub-pixel 201, the extension direction of the second display sub-pixel 102, the extension direction of the second anti-peeping sub-pixel 202, the extension direction of the third display sub-pixel 103, and the extension direction of the third anti-peeping sub-pixel 203 are all the same.

In some embodiments of the present disclosure, in the case of non-annular cutting, such as transverse cutting, vertical cutting or oblique cutting, each sub-pixel, for example, all sub-pixels, can be subjected to the same cutting mode. For example, the same cutting mode may include transverse cutting, vertical cutting or oblique cutting, and two sub-pixels formed by cutting the sub-pixel may have the same size or the same area, and may also have different sizes or different areas.

For example, as shown in FIG. 7A, in the pixel arrangement provided by the embodiments of the present disclosure, the display sub-pixels 100 are obliquely arranged, the anti-peeping sub-pixels 200 are obliquely arranged, and the display sub-pixels 100 and the anti-peeping sub-pixels 200 have the same oblique angle.

In some embodiments of the present disclosure, in the case of oblique cutting, obliquely arranged display sub-pixels or obliquely arranged anti-peeping sub-pixels can be formed.

In the embodiments of the present disclosure, the oblique arrangement of the sub-pixels refers to that the sub-pixels are obliquely arranged relative to the direction X and the direction Y. The same oblique angle of the sub-pixels refers to that the included angle between the extension direction of the sub-pixels and the direction X is the same, or the same oblique angle of the sub-pixels refer to that the included angle between the extension direction of the sub-pixels and the direction Y is the same. For example, in the case that the sub-pixels are obliquely arranged, the extension direction of the sub-pixels and the direction X form an acute included angle, and the extension direction of the sub-pixels and the direction Y form an acute included angle. The acute included angle between the extension direction of the sub-pixels and the direction X can be the same as or different from the acute included angle between the extension direction of the sub-pixels and the direction Y.

For example, one of the direction X and the direction Y can be the extension direction of a long edge of a display region, and the other one of the direction X and the direction Y can be the extension direction of a short edge of the display region, but it is not limited to this. For example, the display region can be an area in which the sub-pixels are arranged. For example, the display region can be an area used for arranging the sub-pixels or the pixels.

For example, in the pixel arrangement, the area of the first anti-peeping sub-pixel 201 is smaller than or equal to that of the first display sub-pixel 101, the area of the second anti-peeping sub-pixel 202 is smaller than or equal to that of the second display sub-pixel 102, and the area of the third anti-peeping sub-pixel 203 is smaller than or equal to that of the third display sub-pixel 103.

In the embodiment of the present disclosure, the area of the anti-peeping sub-pixel is smaller than or equal to that of the display sub-pixel.

In FIG. 13, that the area of the anti-peeping sub-pixel is smaller than that of the display sub-pixel is taken as an example for illustrating. As shown in the FIG. 13, the area of the first anti-peeping sub-pixel 201 is smaller than that of the first display sub-pixel 101, the area of the second anti-peeping sub-pixel 202 is smaller than that of the second display sub-pixel 102, and the area of the third anti-peeping sub-pixel 203 is smaller than that of the third display sub-pixel 103. In other modes adopting transverse cutting, vertical cutting or oblique cutting, the area of the anti-peeping sub-pixel may also be smaller than that of the display sub-pixel.

In the case of annular cutting, the area of the anti-peeping sub-pixel may also be smaller than that of the display sub-pixel. As shown in FIG. 5, FIG. 8, and FIG. 12, the area of the first anti-peeping sub-pixel 201 is smaller than that of the first display sub-pixel 101, the area of the second anti-peeping sub-pixel 202 is smaller than that of the second display sub-pixel 102, and the area of the third anti-peeping sub-pixel 203 is smaller than that of the third display sub-pixel 103.

For example, as shown in FIG. 2 to FIG. 4, in the pixel arrangement provided by the embodiment of the present disclosure, the plurality of pixel groups 12 are arranged in an array in the direction X and the direction Y.

For example, as shown in FIG. 7A and FIG. 8, one sub-pixel SP1, two sub-pixels SP2 and one sub-pixel SP3 form the repeat unit RP. The plurality of repeat units RP are arranged in an array.

At least one embodiment of the present disclosure provides the pixel arrangement, which can be a switchable anti-peeping display pixel arrangement mode adapted to an AMOLED component, but it is not limited to this.

Dotted triangles in FIG. 2 to FIG. 13 show a white-dot pixel structure. The pixel units 10 are of a white-dot pixel structure, and the pixel units 20 are of an anti-peeping white-dot pixel structure.

In FIG. 2 to FIG. 13, the following is taken as an example that the first display sub-pixel 101 and the first anti-peeping sub-pixel 201 are configured to emit red light, the second display sub-pixel 102 and the second anti-peeping sub-pixel 202 are configured to emit green light, and the third display sub-pixel 103 and the third anti-peeping sub-pixel 203 are configured to emit blue light. That is, the first display sub-pixel 101 and the first anti-peeping sub-pixel 201 are red sub-pixels (R), the second display sub-pixel 102 and the second anti-peeping sub-pixel 202 are green sub-pixels (G), and the third display sub-pixel 103 and the third anti-peeping sub-pixel 203 are blue sub-pixels (B).

As shown in FIG. 2, R and G are not completely consistent in height, so there will be a little deviation on center distance of the R and the G of the two white-dot pixel structures. The three sub-pixels R, G and B in FIG. 2 are equally divided, and non-uniform division can also be actually performed according to conditions.

As shown in FIG. 3, the sub-pixels are divided in a vertical cutting mode, and the R and the G of the two white-dot pixel structures are the same in center distance. The three sub-pixels R, G and B in FIG. 3 are all equally divided, and non-uniform division can also be actually performed according to conditions.

As shown in FIG. 4, the sub-pixels are divided in an annular cutting mode, and the R and the G of the two white-dot pixel structures are the same in center distance. The three sub-pixels R, G and B in FIG. 4 are all equally divided, and non-uniform division can also be actually performed according to conditions.

As shown in FIG. 7A, the sub-pixels are divided in 45° and 135° oblique cutting modes, and the R and the G of the two white-dot pixel structures are basically consistent in center distance. The three sub-pixels R, G and B in FIG. 7 are all equally divided, and non-uniform division can also be actually performed according to conditions. Besides the oblique mode in the figure, it may include other oblique combination modes other than 45° and 135°.

As shown in FIG. 8, the sub-pixels are divided in an annular cutting mode, and the R and the G of the two white-dot pixel structures are the same in center distance. The three sub-pixels R, G and B in FIG. 8 are all equally divided, and non-uniform division can also be actually performed according to conditions.

As shown in FIG. 10, the red sub-pixels and the blue sub-pixels are shared pixels, the sub-pixels are divided in transverse and vertical cutting modes, the R and the G are inconsistent in the dividing mode, and there is a deviation on the center distance of the R and the G of the two white-dot pixels. The three sub-pixels R, G and B in FIG. 10 are all equally divided, and non-uniform division can also be actually performed according to conditions. The sub-pixels R, G and B can be partially transversely divided and partially vertically divided.

As shown in FIG. 11, the sub-pixels are divided in transverse and vertical cutting modes, the R and G sub-pixels are inconsistent in the dividing mode, and compared with the pixel arrangement shown in FIG. 10, the deviation on the center distance of the R and the G of two white-dot pixel structures in the pixel arrangement shown in FIG. 11 is reduced. The three sub-pixels R, G and B in FIG. 11 are all equally divided, and non-uniform division can also be actually performed according to conditions. The sub-pixels R, G and B can be partially transversely divided and partially vertically divided.

As shown in FIG. 12, the sub-pixels are divided in the annular cutting mode, and the R and the G of the two white-dot pixel structures are the same in center distance. The three sub-pixels R, G and B in FIG. 12 are equally divided, and non-uniform division can also be actually performed according to conditions.

Besides transverse, vertical and annular cutting, there are 45° or 135° oblique and irregular-direction dividing modes.

In the embodiments of the present disclosure, the R and the G of the two white-dot pixel structures are the same in center distance, which facilitates the improvement of the display effect.

The cutting in the embodiments of the present disclosure is performed on the basis of an original pixel arrangement without anti-peeping display, the sub-pixel is divided into two sub-pixels, one of the two sub-pixels is used as the anti-peeping sub-pixel, and the other one of the two sub-pixels is used as the display sub-pixel.

An embodiment of the present disclosure further provides a display substrate, which includes a base substrate BS, and a plurality of pixels arranged on the base substrate BS; and the plurality of pixels adopt any pixel arrangement described above.

For example, the base substrate can be a flexible substrate to form a flexible display substrate.

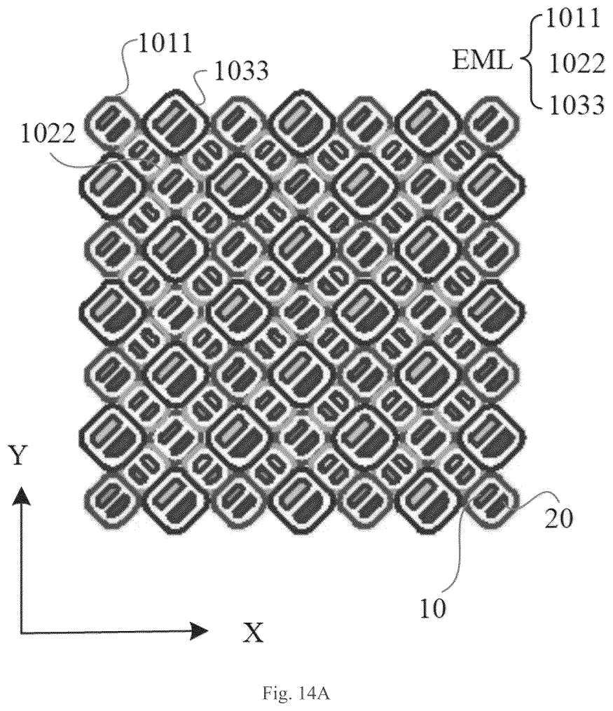

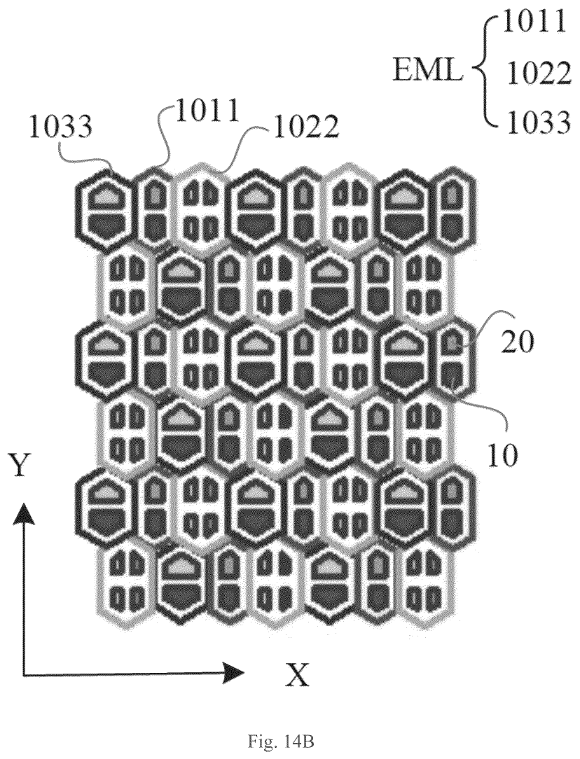

FIG. 14A is a schematic diagram of a display substrate provided by an embodiment of the present disclosure. FIG. 14B is a schematic diagram of a display substrate provided by an embodiment of the present disclosure.

As shown in FIG. 14A and FIG. 14B, the display substrate includes a light emitting layer EML, and the light emitting layer EML includes a first light emitting part 1011, a second light emitting part 1022, and a third light emitting part 1033. The orthographic projection of the first light emitting part 1011 on the base substrate covers the orthographic projections of the first display sub-pixel 101 and the first anti-peeping sub-pixel 201 on the base substrate, the orthographic projection of the second light emitting part 1022 on the base substrate covers the orthographic projections of the second display sub-pixel 102 and the second anti-peeping sub-pixel 202 on the base substrate, and the orthographic projection of the third light emitting part 1033 on the base substrate covers the orthographic projections of the third display sub-pixel 103 and the third anti-peeping sub-pixel 203 on the base substrate. Therefore, the first display sub-pixel 101 and the first anti-peeping sub-pixel 201 emit light of the same color, the second display sub-pixel 102 and the second anti-peeping sub-pixel 202 emit light of the same color, and the third display sub-pixel 103 and the third anti-peeping sub-pixel 203 emit light of the same color.

As shown in FIG. 14A and FIG. 14B, each light emitting part corresponds to one anti-peeping sub-pixel 20 and one display sub-pixel 10.

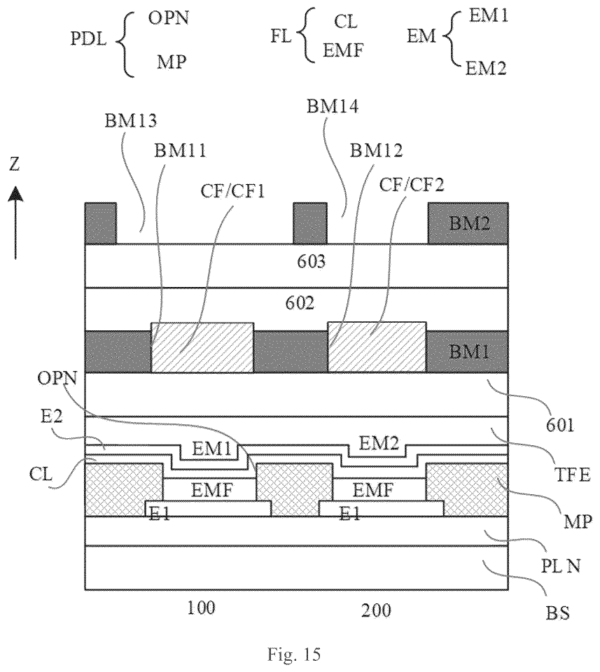

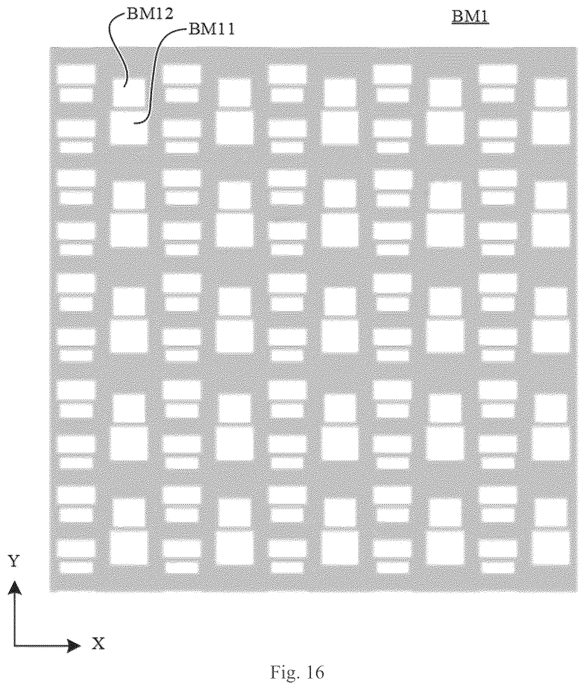

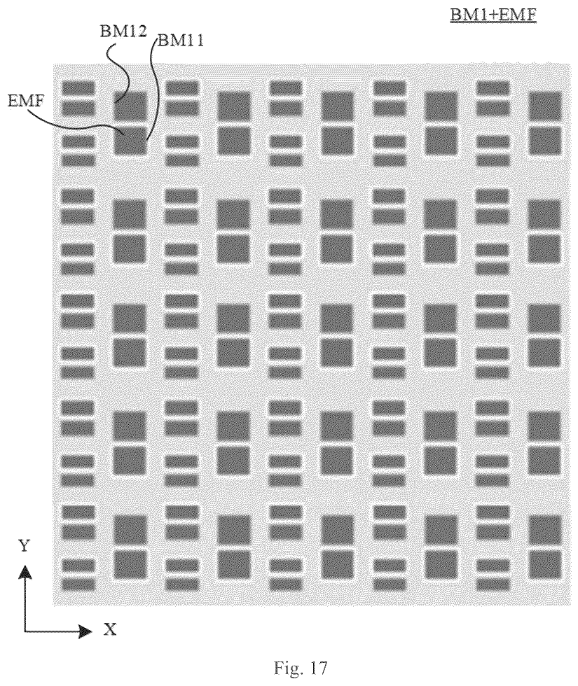

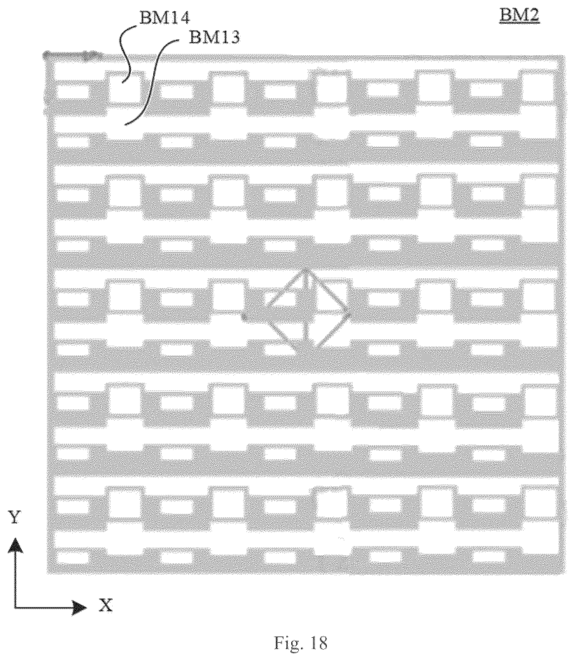

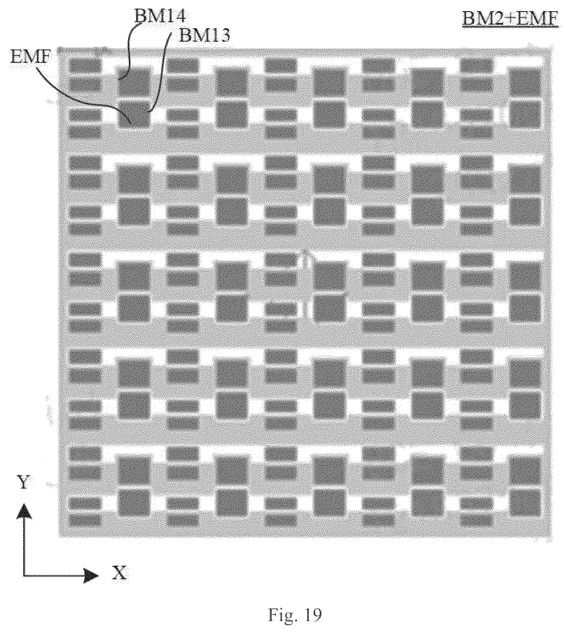

FIG. 15 is a sectional view of a display substrate provided by an embodiment of the present disclosure. FIG. 16 is a plan view of a black matrix BM1 in a display substrate provided by an embodiment of the present disclosure. FIG. 17 is a plan view of a black matrix BM1 and a local light emitting layer EMF in a display substrate provided by an embodiment of the present disclosure. FIG. 18 is a plan view of a black matrix BM2 in a display substrate provided by an embodiment of the present disclosure. FIG. 19 is a plan view of a black matrix BM2 and a local light emitting layer EMF in a display substrate provided by an embodiment of the present disclosure.

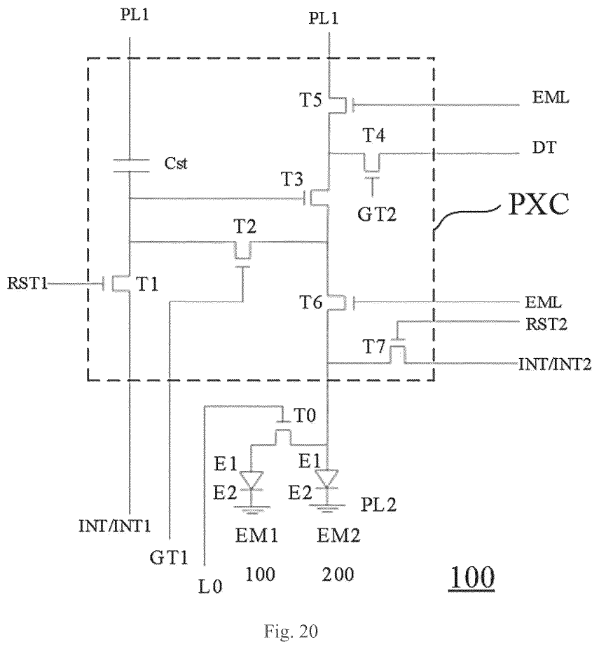

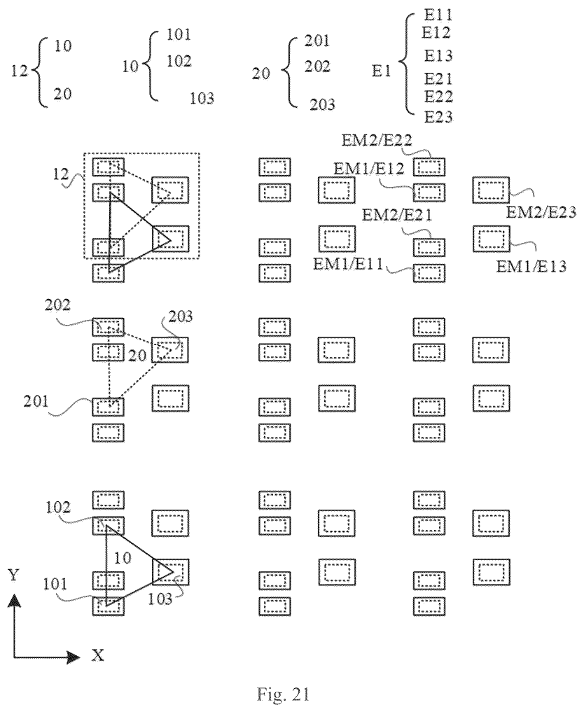

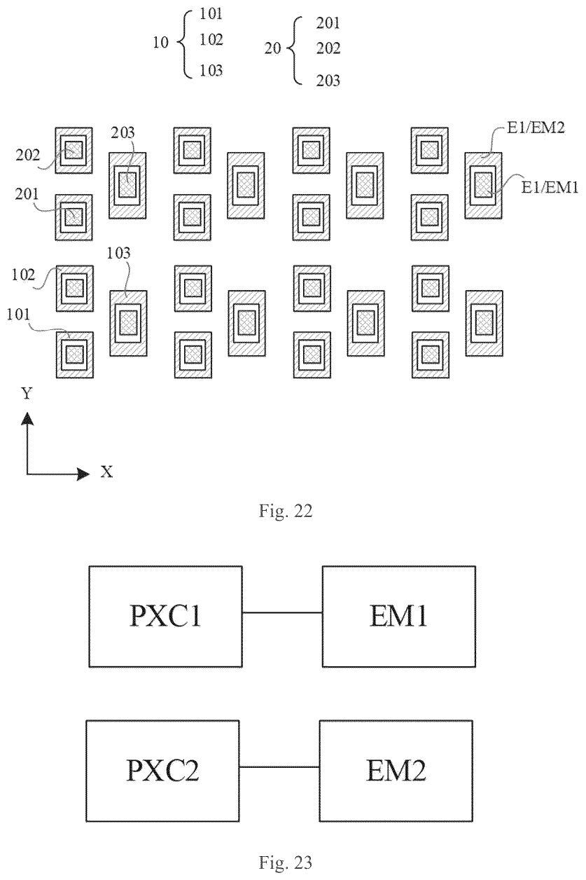

FIG. 20 is a schematic diagram of connection between a pixel circuit and a light emitting element in a display substrate provided by an embodiment of the present disclosure. FIG. 21 is a schematic diagram of a display substrate provided by an embodiment of the present disclosure. FIG. 22 is a schematic diagram of a display substrate provided by an embodiment of the present disclosure. FIG. 23 is a schematic diagram of connection between a pixel circuit and a light emitting element in a display substrate provided by another embodiment of the present disclosure.

For example, as shown in FIG. 15, in the display substrate provided by the embodiment of the present disclosure, the display substrate further includes a pixel defining layer PDL, the pixel defining layer PDL is provided with a main body part MP and a pixel opening OPN, and the display sub-pixel 100 and the anti-peeping sub-pixel 200 are separated by a part of the main body part MP.

As shown in FIG. 15, the display substrate includes the display sub-pixel 100 and the anti-peeping sub-pixel 200, and the display sub-pixel 100 and the anti-peeping sub-pixel 200 are spaced apart from each other.

As shown in FIG. 15, FIG. 21 and FIG. 22, in the display substrate provided by the embodiment of the present disclosure, the display sub-pixel 100 includes a light emitting element EM1; the anti-peeping sub-pixel 200 includes a light emitting element EM2; each of the light emitting element EM1 and the second light emitting element EM1 includes a first electrode E1, a second electrode E2, and a light emitting functional layer FL located between the first electrode E1 and the second electrode E2; the first electrode E1 is closer to the base substrate BS than the second electrode E2; and the first electrode E1 of the light emitting element EM1 and the first electrode E2 of the light emitting element EM2 are spaced apart from each other.

As shown in FIG. 2 to FIG. 5, FIG. 7A to FIG. 8, and FIG. 10 to FIG. 13, in the same pixel group, the closest anti-peeping sub-pixel 200 and display sub-pixel 100 have the same light emitting color. For example, the closest anti-peeping sub-pixel 200 and display sub-pixel 100 may refer to the closest distance between the centers of the anti-peeping sub-pixel 200 and the display sub-pixel 100. In the case that one of the anti-peeping sub-pixel 200 and the display sub-pixel 100 is located within the other, the distance from the anti-peeping sub-pixel 200 to the display sub-pixel 100 is the closest, for example, the distance from the anti-peeping sub-pixel 200 to the display sub-pixel 100 can be regarded as 0.

For example, as shown in FIG. 15, the light emitting functional layer FL includes a common layer CL, and a local light emitting layer (non-common light emitting layer) EMF; the common layer CL is shared by a plurality of sub-pixels; the local light emitting layers (EMFs) of the plurality of sub-pixels are separated from each other. For example, the local light emitting layer EMF includes the light emitting layer EML. The local light emitting layer EMF may further include a hole injection layer and a hole transport layer, and materials of the hole injection layer, the hole transport layer, and the light emitting layer EML are located in pixel openings defined by the pixel defining layer PDL, the common layer CL includes the electron injection layer. Definitely, the structure of the light emitting functional layer FL is not limited to the above and can be selected as needed.

As shown in FIG. 15, the common layer CL is shared by the plurality of sub-pixels (light emitting elements EM), and the local light emitting layers EMF of different sub-pixels are spaced apart from each other. For example, the local light emitting layer EMF is located in one sub-pixel (light emitting element EM).

For example, as shown in FIG. 15, a planarization layer PLN is arranged on the base substrate BS, the first electrodes E1 are arranged on the planarization layer PLN, the light emitting functional layer FL is arranged on the first electrodes E1, and the second electrode E2 is arranged on the light emitting functional layer FL. An encapsulation layer TFE is arranged on the second electrode E2. For example, the encapsulation layer TFE includes a thin film encapsulation layer. An insulating material layer 601 is arranged on the encapsulation layer TFE. The black matrix BM1 and the color filter layer CF are arranged on the insulating material layer 601, and an insulating material layer 602 is arranged on the black matrix BM1 and the color filter layer CF. An insulating material layer 603 is arranged on the insulating material layer 602, and the black matrix BM2 is arranged on the insulating material layer 603. The insulating material layer 601 and the insulating material layer 602 can be transparent adhesive layers. The transparent adhesive layer includes Optically Clear Adhesive (OCA). The insulating material layer 603 can include an organic insulating material, for example, resin, but it is not limited to this. The insulating material layer 603 can be manufactured by an ink-jet printing process.

In FIG. 15, a structure between the planarization layer PLN and the base substrate BS is omitted. For example, a pixel circuit is arranged between the planarization layer PLN and the base substrate BS.

As shown in the FIG. 15, the color filter layer CF includes a color filter part CF1 and a color filter part CF2. The color filter part CF1 corresponds to the display sub-pixel 100, and the color filter part CF2 corresponds to the anti-peeping sub-pixel 200.

For example, as shown in the FIG. 15 to FIG. 19, the display substrate provided by the embodiment of the present disclosure further includes the black matrix BM1 and the black matrix BM2, the black matrix BM1 is located on the plurality of pixels, and the black matrix BM2 is located on the black matrix BM1. For example, as shown in FIG. 15 to FIG. 19, the black matrix BM1 is located on the side of the plurality of pixels facing away from the base substrate BS, and the black matrix BM2 is located on the side of the black matrix BM1 facing away from the base substrate BS.

For example, as shown in FIG. 15 to FIG. 19, the black matrix BM1 is provided with a first hollowed-out region BM11 and a second hollowed-out region BM12; the black matrix BM2 is provided with a third hollowed-out region BM13 and a fourth hollowed-out region BM14; an orthographic projection of the first hollowed-out region BM11 on the base substrate BS is overlapped with the orthographic projection of the display sub-pixel 100 on the base substrate BS; an orthographic projection of the third hollowed-out region BM13 on the base substrate BS is overlapped with the orthographic projection of the display sub-pixel 100 on the base substrate BS; an orthographic projection of the second hollowed-out region BM12 on the base substrate BS is overlapped with the orthographic projection of the anti-peeping sub-pixel 200 on the base substrate BS; an orthographic projection of the fourth hollowed-out region BM14 on the base substrate BS is overlapped with the orthographic projection of the anti-peeping sub-pixel 200 on the base substrate BS; the area of the third hollowed-out region BM13 is larger than that of the first hollowed-out region BM11; and the area of the fourth hollowed-out region BM14 is equal to that of the second hollowed-out region BM12.

According to the display substrate provided by the embodiment of the present disclosure, the area of the third hollowed-out region BM13 is larger than that of the first hollowed-out region BM11, and the area of the fourth hollowed-out region BM14 is equal to that of the second hollowed-out region BM12, which facilitates the sharing of the display sub-pixels 100 in the sharing state, and anti-peeping of the anti-peeping sub-pixels 200 in the anti-peeping state.

According to the display substrate provided by the embodiment of the present disclosure, the anti-peeping sub-pixels 200 are shielded by the black matrix BM1 and the black matrix BM2, FIG. 16 is a top view of the black matrix BM1, FIG. 18 is a top view of the black matrix BM2, the black matrix BM1 is used a Color filter on encapsulation COE for replacing a structure of a polarizer; the opening (the first hollowed-out region BM11) of the black matrix BM1 corresponding to the display sub-pixel 100 can be 3 μm, and the size of the opening (the second hollowed-out region BM12 of the black matrix BM1 corresponding to the anti-peeping sub-pixel 200 is same as that of the local light emitting layer EMF; and the black matrix BM2 is configured to shield the anti-peeping sub-pixel 200, the display sub-pixels 100 are not shielded by the black matrix BM2, and the size of the opening (the fourth hollowed-out region BM14) of the black matrix BM2 corresponding to the anti-peeping sub-pixel is same as that of the local light emitting layer EMF; and the brightness at a 45° viewing angle in the anti-peeping state can be reduced to 8% by optical simulation.

For example, in the display substrate provided by the embodiment of the present disclosure, at least one of the plurality of display sub-pixels 100 in the pixel units 10 and at least one of the plurality of anti-peeping sub-pixels 200 in the pixel units 20 share one pixel circuit PXC.

As shown in FIG. 20, the display sub-pixel 100 and the anti-peeping sub-pixel 200 share one pixel circuit PXC.

For example, as shown in FIG. 20, in the display substrate provided by the embodiment of the present disclosure, the pixel circuit PXC includes a switching transistor T0, the pixel circuit PXC is connected to the anti-peeping sub-pixel 200, and the pixel circuit PXC is connected to the display sub-pixel 100 through the switching transistor T0. For example, as shown in FIG. 20, the pixel circuit PXC is connected to the first electrode E1 of the anti-peeping sub-pixel 200, and the pixel circuit PXC is connected to the first electrode E1 of the display sub-pixel 100 through the switching transistor T0.

In the display substrate provided by the embodiment of the present disclosure, the switchable anti-peeping display can be realized through the switching transistor T0. In the case that the switching transistor T0 is turned off, and only the anti-peeping sub-pixel 200 (the light emitting element EM2) is lightened, it is in the anti-peeping state; and in the case that the switching transistor T0 is turned on, the anti-peeping sub-pixel 200 (the light emitting element EM2) and the display sub-pixel 100 (the light emitting element EM1) are both lightened, it is in the sharing state.

As shown in FIG. 20, the pixel circuit PXC includes six switching transistors (T1-T2, T4-T7), one driving transistor T3 and one storage capacitor Cst. The six switching transistors are respectively a data writing transistor T4, a threshold compensation transistor T2, a light emitting control transistor T5, a light emitting control transistor T6, a reset transistor T1 and a reset transistor T7. A light emitting element 100b includes the first electrode E1, the second electrode E2, and the light emitting functional layer between the first electrode E1 and the second electrode E2. For example, the first electrode E1 is anode, and the second electrode E2 is cathode.

As shown in FIG. 20, a gate electrode of the light emitting control transistor T5 and a gate electrode of the light emitting control transistor T6 are both connected to a light emitting control signal line EML. A gate electrode of the data writing transistor T4 is connected to a scan line GT2. A gate electrode of the reset transistor T7 is connected to a reset control signal line RST2. A gate electrode of the threshold compensation transistor T2 is connected to a gate line GT1. A gate electrode of the reset transistor T1 is connected to a reset control signal line RST1.

As shown in FIG. 20, one end of the storage capacitor Cst is connected to a gate electrode of the driving transistor T3, and the other end of the storage capacitor Cst is connected to a power line PL1; and one electrode of the light emitting control transistor T5 is connected to the driving transistor T3, and the other electrode of the light emitting control transistor T5 is connected to the power line PL1.

As shown in FIG. 20, the second electrode E2 is connected to a power line PL2. The second electrode E2 of the display sub-pixel 100 and the second electrode E2 of the anti-peeping sub-pixel 200 are both connected to the power line PL2.

In FIG. 20, it is described by taking the pixel circuit of 7T1C as an example. However, the embodiment of the present disclosure does not limit the structure of the pixel circuit, and a proper pixel circuit can be selected as needed, namely the setting condition of the transistors and the setting condition of the capacitors in the pixel circuit can be determined as needed.

For example, the material of the first electrode E1 includes a conductive material, such as at least one of silver (Ag) or indium tin oxide (ITO), but it is not limited to this, it can be determined as needed. For example, the first electrode E1 is of a stacked structure of ITO/Ag/ITO layers, but it is not limited to this.

For example, the material of the second electrode E2 includes a conductive material, such as silver (Ag), but it is not limited to this, it can be determined as needed.

FIG. 21 shows the first electrodes E1 of the light emitting elements EM1 and the first electrodes E1 of the light emitting elements EM2. The first electrodes E1 include first electrodes E11 of the first display sub-pixels 101, first electrodes E12 of the second display sub-pixels 102, first electrodes E13 of the third display sub-pixels 103, first electrodes E21 of the first anti-peeping sub-pixels 201, first electrodes E22 of the second anti-peeping sub-pixels 202, and first electrodes E23 of the third anti-peeping sub-pixels 203.

As shown in FIG. 21, the first electrode E11 of the first display sub-pixel 101, the first electrode E12 of the second display sub-pixel 102, the first electrode E13 of the third display sub-pixel 103, the first electrode E21 of the first anti-peeping sub-pixel 201, the first electrode E22 of the second anti-peeping sub-pixel 202 and the first electrode E23 of the third anti-peeping sub-pixel 203 are spaced apart from one another.

For example, the first electrodes E1 of the display sub-pixels 100 and the first electrodes E1 of the anti-peeping sub-pixels 200 are formed by the same patterning process using the same film layer.

As shown in FIG. 21 and FIG. 22, the first electrode E1 of the light emitting element EM1 and the first electrode E1 of the light emitting element EM2 are spaced apart from each other.

As shown in FIG. 21 and FIG. 22, a plurality of first electrodes E1 are spaced apart from one another, and the first electrode E1 of the display sub-pixel 100 and the first electrode E1 of the anti-peeping sub-pixel 200 are spaced apart from each other.

In the embodiment of the present disclosure, the display sub-pixel 100 includes the light emitting element EM1, and the anti-peeping sub-pixel 200 includes the light emitting element EM2.

In FIG. 20, that the display sub-pixel and the anti-peeping sub-pixel share one pixel circuit is taken as an example for illustrating. However, the embodiment of the present disclosure is not limited to this. For example, in other embodiments, as shown in FIG. 23, the display sub-pixel and the anti-peeping sub-pixel can be controlled by the respective pixel circuits respectively in order to perform accurate circuit control. That is, the display sub-pixel adopts the first pixel circuit PXC1, the first pixel circuit PXC1 is connected to the first electrode E1 of the light emitting element EM1, and the anti-peeping sub-pixels adopt second pixel circuits PXC2, the second pixel circuit PXC2 is connected to the first electrode E1 of the light emitting element EM2; and the first pixel circuit PXC1 and the second pixel circuit PXC2 are different and can control the light emitting element EM1 and the light emitting element EM2 independently.

In some accompanying drawings of the embodiment of the present disclosure, the plan view shows the direction Y and the direction X, and the sectional view shows the direction Z. The direction Y and the direction X are both directions parallel to a main surface of the base substrate BS. A direction Z is a direction perpendicular to the main surface of the base substrate BS. For example, the direction Y intersects the direction X. In the embodiment of the present disclosure, that the direction Y is perpendicular to the direction X is taken as an example for illustrating. As shown in the sectional views, the main surface of the base substrate BS is a surface, which is used for manufacturing various elements, of the base substrate BS. As shown in the sectional views, an upper surface of the base substrate BS is the main surface of the base substrate BS.

An embodiment of the present disclosure provides a display device, which includes any one of the display substrates as described above.

The pixel arrangement provided by the embodiment of the present disclosure can be applied to an OLED display device, and definitely, it can also be applied to a liquid crystal display device, besides the OLED display device.

For example, the display device can include any product or component with a display function, such as a television, a digital camera, a mobile phone, a watch, a tablet personal computer, a notebook computer and a navigator, which is provided with the display substrate with any one of the pixel arrangements.

The following statements need to be explained.

(1) Unless otherwise defined, all the technical and scientific terms used herein have the same meanings as commonly understood by one of ordinary skill in the art to which the present disclosure belongs. The terms “first,” “second,” etc., which are used in the present disclosure, are not intended to indicate any sequence, amount or importance, but distinguish various components.

(2) In the drawings of the embodiments of the present disclosure, only the structures related to the embodiments of the present disclosure are involved, and other structures can refer to the common design(s).

(3) For the sake of clarity, in the drawings used to describe the embodiments of the present disclosure, the thickness of a layer or region is exaggerated. It can be understood that when an element such as a layer, film, region, or substrate is referred to as being “on” or “under” another element, the element can be “directly” “on” or “under” the other element, or there may be intermediate elements.

(4) In the case of no conflict, the features in the same embodiment and different embodiments of the present disclosure can be combined with each other.

The above are only specific embodiments of the present disclosure, but the protection scope of the present disclosure is not limited thereto. Any person skilled in the art can easily conceive of changes or substitutions within the technical scope disclosed in the present disclosure, and these changes or substitutions should be covered within the protection scope of the present disclosure. Therefore, the protection scope of the present disclosure should be subject to the protection scope of the claims.

1. A pixel arrangement, comprising a plurality of pixel groups, wherein
each of the plurality of pixel groups comprises: a first pixel unit and a second pixel unit;
the first pixel unit comprises a plurality of display sub-pixels,
the second pixel unit comprises a plurality of anti-peeping sub-pixels,
the first pixel unit is configured to display in a first state, and the second pixel unit is configured to display in a second state; and
in the same pixel group, a first region defined by center connecting lines of the plurality of display sub-pixels is overlapped with a second region defined by center connecting lines of the plurality of anti-peeping sub-pixels.

2. The pixel arrangement according to claim 1, wherein the second pixel unit is also configured to display in the first state.

3. The pixel arrangement according to claim 1, wherein each of the plurality of display sub-pixels is annular and is provided with an opening, and one of the plurality of anti-peeping sub-pixels is arranged in the opening.

4. The pixel arrangement according to claim 1, wherein an area of the first region is equal to that of the second region.

5. The pixel arrangement according to claim 1, wherein the plurality of display sub-pixels comprise a first display sub-pixel, a second display sub-pixel, and a third display sub-pixel; the plurality of anti-peeping sub-pixels comprise a first anti-peeping sub-pixel, a second anti-peeping sub-pixel, and a third anti-peeping sub-pixel; the first display sub-pixel and the first anti-peeping sub-pixel are configured to emit light of a first color; the second display sub-pixel and the second anti-peeping sub-pixel are configured to emit light of a second color; and the third display sub-pixel and the third anti-peeping sub-pixel are configured to emit light of a third color.

6. The pixel arrangement according to claim 5, wherein the first display sub-pixel is annular and is provided with a first opening, and the first anti-peeping sub-pixel is arranged in the first opening; the second display sub-pixel is annular and is provided with a second opening, and the second anti-peeping sub-pixel is arranged in the second opening; and the third display sub-pixel is annular and is provided with a third opening, and the third anti-peeping sub-pixel is arranged in the third opening.

7. The pixel arrangement according claim 5, wherein the center connecting line of the first display sub-pixel and the second display sub-pixel coincides with the center connecting line of the first anti-peeping sub-pixel and the second anti-peeping sub-pixel.

8. The pixel arrangement according to claim 5, wherein the first display sub-pixel and the first anti-peeping sub-pixel are adjacent to each other, the second display sub-pixel and the second anti-peeping sub-pixel are adjacent to each other, and the third display sub-pixel and the third anti-peeping sub-pixel are adjacent to each other.

9. The pixel arrangement according to claim 8, wherein in the same pixel group, the center connecting line of the first display sub-pixel and the second display sub-pixel is not overlapped or is partially overlapped with the center connecting line of the first anti-peeping sub-pixel and the second anti-peeping sub-pixel.

10. The pixel arrangement according to claim 8, wherein an extension direction of the first display sub-pixel is the same as that of the first anti-peeping sub-pixel, an extension direction of the second display sub-pixel is the same as that of the second anti-peeping sub-pixel, and an extension direction of the third display sub-pixel is the same as that of the third anti-peeping sub-pixel.

11. (canceled)

12. The pixel arrangement according to claim 10, wherein each of the plurality of display sub-pixels is obliquely arranged, each of the plurality of anti-peeping sub-pixels is obliquely arranged, and the display sub-pixel and the anti-peeping sub-pixel have the same oblique angle.

13. The pixel arrangement according to claim 5, wherein an area of the first anti-peeping sub-pixel is smaller than or equal to an area of the first display sub-pixel, an area of the second anti-peeping sub-pixel is smaller than or equal to an area of the second display sub-pixel, and an area of the third anti-peeping sub-pixel is smaller than or equal to an area of the third display sub-pixel.

14. The pixel arrangement according to claim 5, wherein a center distance of the first display sub-pixel and the second display sub-pixel is the same as a center distance of the first anti-peeping sub-pixel and the second anti-peeping sub-pixel.

15. A display substrate, comprising:
a base substrate; and
a plurality of pixels arranged on the base substrate; and
the plurality of pixels adopt the pixel arrangement according to claim 1.

16. The display substrate according to claim 15, wherein at least one of the plurality of display sub-pixels in the first pixel unit and at least one of the plurality of anti-peeping sub-pixels in the second pixel unit share one same pixel circuit.

17. The display substrate according to claim 16, wherein the pixel circuit comprises a switching transistor; and the pixel circuit is connected to a first electrode of one of the plurality of anti-peeping sub-pixels, and the pixel circuit is connected to a first electrode of one of the plurality of display sub-pixels through the switching transistor.

18. The display substrate according to claim 15, further comprising a pixel defining layer, wherein the pixel defining layer is provided with a main body part and a pixel opening, and one of the plurality of display sub-pixels and one of the plurality of anti-peeping sub-pixels are separated by a part of the main body part.

19. The display substrate according to claim 15, further comprising a first black matrix and a second black matrix, wherein the first black matrix is located on a side of the plurality of pixels facing away from the base substrate, and the second black matrix is located on a side of the first black matrix facing away from the base substrate; the first black matrix is provided with a first hollowed-out region and a second hollowed-out region; and the second black matrix is provided with a third hollowed-out region and a fourth hollowed-out region;
an orthographic projection of the first hollowed-out region on the base substrate is overlapped with an orthographic projection of one of the plurality of display sub-pixels on the base substrate; an orthographic projection of the third hollowed-out region on the base substrate is overlapped with the orthographic projection of the display sub-pixel on the base substrate;
an orthographic projection of the second hollowed-out region on the base substrate is overlapped with an orthographic projection of one of the plurality of anti-peeping sub-pixels on the base substrate; an orthographic projection of the fourth hollowed-out region on the base substrate is overlapped with the orthographic projection of the anti-peeping sub-pixel on the base substrate;
an area of the third hollowed-out region is larger than that of the first hollowed-out region; and an area of the fourth hollowed-out region is equal to that of the second hollowed-out region.

20. The display substrate according to claim 15, wherein each of the plurality of display sub-pixels comprises a first light emitting element; each of the plurality of anti-peeping sub-pixels comprises a second light emitting element; each of the first light emitting element and the second light emitting element comprises a first electrode, a second electrode, and a light emitting functional layer located between the first electrode and the second electrode; the first electrode is closer to the base substrate than the second electrode; the first electrode of the first light emitting element and the first electrode of the second light emitting element are spaced apart from each other; and in the same pixel group, the anti-peeping sub-pixel and display sub-pixel that are closest in distance have the same light emitting color.

21. A display device, comprising the display substrate according to claim 15.
